(19) United States
(12) Patent Application Publication
(10) Pub. No.: US 2004/0098656 A1
(43) Pub. Date: May 20, 2004

(54) Digital information signal recording method and recording medium

(76) Inventors: Hirotoshi Ohno, Yokohama-shi (JP); Hiroyoshi Yoshikawa, Zama-shi (JP); Nobuchika Ochi, Yokohama-shi (JP)

Correspondence Address: NATH & ASSOCIATES, PLLC, Sixth Floor, 1030 15th Street, N.W., Washington, DC, 20005, US

(21) Appl. No.: 10/623,585

(22) Filed: Jul. 22, 2003

(30) Foreign Application Priority Data
Jul. 26, 2002 (JP) P2002-218249

(51) Int. Cl. H03M 13/00

(52) U.S. Cl. 714/758

(57) ABSTRACT

There is disclosed a recording method in which an input data word of p bits is converted to a code word of q bits, and modulation signals of a one-frame unit obtained by NRZI-converting a string of code words connected to one another while strictly keeping a predetermined run length limitation rule and an error correction code are continuously arranged in a state of a plurality of frames to constitute data for copy prevention. The data for copy prevention and a p-q modulated digital information signal are recorded on a recording medium. In this case, the error correction code of the data for copy prevention is beforehand set to the same value as that of an error correction code at a copy time, which is added in copying a reproduction signal of the data for copy prevention onto another recording medium. The string of code words of the data for copy prevention is beforehand coded to be error-correctable by the error correction code beforehand set to the same value as that of the error correction code at the copy time.

### BACKGROUND OF THE INVENTION

1. Technical Field of the Invention

The present invention relates to a digital information signal recording method and recording medium in which illegal copy of digital information signals recorded on recording mediums such as an optical disk and a digital magnetic tape can be prevented in advance while strictly keeping a predetermined run length limitation rules.

2. Description of the Related Art

With arrival of an age of digital multimedia, a large capacity of digital information signals are recorded on an optical disk or a digital magnetic tape.

As to optical disks for exclusive use in reproduction, such as a compact disc (CD) on which music information is recorded and a CD-read only memory (CD-ROM) on which computer data is recorded, various types of digital information signals described above can be recorded with a high density in a track formed in a spiral or concentric shape on a disc-shaped substrate. Additionally, a desired track can be accessed at a high speed at a reproduction time. Moreover, since the optical disks are suitable for mass production and can inexpensively be obtained, the disks have frequently been used.

Moreover, the digital magnetic tapes on which PCM music information is recorded can be played back over a longer time as compared with the optical disks, and have frequently been used.

It is to be noted that the optical disk recorded and/or played back as the recording medium on which the digital information signals are recorded using an optical pickup will be described hereinafter. The digital magnetic tape is largely different only in that a magnetic head is used at a time of the recording and/or reproducing. Therefore, the description of the digital magnetic tape will be omitted.

In the above-described optical disks such as CD and CD-ROM, the digital information signals are converted to a digital pit string including concave pits and convex lands. This pit string is carved as a spiral or concentric recording track. A stamper board on which a signal surface is recorded in this manner is attached to an injection molding machine. Thereafter, a transparent resin material is used to transfer the signal surface of the stamper board onto a disc-shaped transparent disk substrate which has an outer diameter of 120 mm or 80 mm, center hole diameter of 15 mm, and substrate thickness of 1.2 mm. Furthermore, a reflective film, and protective film are formed in that order on the transferred signal surface for exclusive use in reproduction.

Moreover, when the optical disk for the exclusive use in reproduction is played back, the signal surface is irradiated with laser beams for reproduction from the optical pickup movably disposed in an optical disk drive on a side of the transparent disk substrate to reproduce the signal surface with return lights of the laser beams from the reflective film formed on the signal surface.

Additionally, copyrights of the music information recorded on the CD and the computer data recorded on the CD-ROM are protected by a copyright law. However, since the information is digital, the signals are not deteriorated. Therefore, a user can illegally copy the information or data into recordable optical disks such as a compact disc-recordable (CD-R) in which one write is possible as such and a compact disc-rewritable (CD-RW) in which a plurality of writes are possible without obtaining a consent from a copyright holder.

The recordable optical disks such as the CD-R and CD-RW have substantially the same appearance shapes as those of the optical disks for the exclusive use in the reproduction such as CD and CD-ROM. However, for the recordable optical disks, a concave trench is spirally or concentrically formed in the transparent disk substrate, and the concave trench is spin-coated with an organic dyestuff to form a recording layer. Furthermore, the reflective film and protective film are formed in that order on the organic dyestuff. Additionally, the recordable optical disks can inexpensively be obtained.

Moreover, when the music information recorded on the CD or the computer data recorded on the CD-ROM is illegally copied into the CD-R or CD-RW, the information or data is recorded in the same signal format as that for the CD and CD-ROM, and therefore this infringes on the copyright.

For example, the copying of the music information recorded on the CD into the CD-R will be described hereinafter in order.

FIG. 1 is an explanatory view of the signal format of the music information recorded on the CD. FIG. 2 is a diagram showing a coding table at an 8-14 modulation time. FIGS. 3A and 3B are explanatory views of a DSV control at the 8-14 modulation time. FIG. 4 is a diagram showing that 98 EFM signals shown in FIG. 1 constitute one block.

First, the music information is recorded on the CD in the signal format which conforms to CD written standards “Read Book”.

In this case, with respect to a pit length recorded on the optical disk, it is generally necessary to limit a minimum run length (minimum pit length or minimum land length) in vies of light transmission properties for the recording/reproducing or in view of physical restrictions concerning pit generation, or to limit a maximum run length (maximum pit length or maximum land length) in view of ease of clock regeneration. It is further necessary to modulate the recording signal so as to have suppressive properties of low-pass components of the recording signal, so that a servo band is protected.

Among modulation systems which satisfy this limitation, in an eight to fourteen modulation (EFM: 8-14 modulation) system for use in the CD, the minimum run length (=also referred to as a minimum reverse interval) is set to 3T (T=period of channel bits), and the maximum run length (=also referred to as a maximum reverse interval) is set to 11T.

That is, music source data AD to be recorded on the CD is digital data, one unit is constituted of upper eight bits (one byte)+lower eight bits (one byte)=16 bits (two bytes), and a plurality of continuous units constitute the music source data AD.

Moreover, when the music source data AD is recorded on a glass board by laser beams at a mastering time, the music source data AD is converted to the signal format of the EFM system so as to obtain a signal form suitable for the recording. The data is recorded onto a glass master board in the form of EFM signals 1 shown in FIG. 1. Thereafter, a metal master board, mother board, and stamper board are successively prepared based on the glass master board by an electroforming treatment. Thereafter, the stamper board is attached to an injection molding machine, and the signal surface of the stamper board is transferred onto the transparent disk substrate to prepare the CD. Therefore, the signal surface of the CD is equivalent to that of the glass master board.

Here, in the format of the EFM signal 1, the inputted music source data AD is divided into input data words D of the upper eight bits and input data words D of the lower eight bits. Referring to a coding table shown in FIG. 2, the input data word D of p bits=8 bits is converted to a run length limited code (hereinafter referred to as the code word C) of q bits=14 bits so as to satisfy a run length limitation rule that the minimum run length is 3T and the maximum run length is 11T. Additionally, as shown in FIG. 1, coupling bits 1b of r bits=3 bits for holding the run length limitation rule and for controlling a digital sum variation (DSV) are added between the converted code words C to form first and second code word strings 1d, if so that the EFM signal 1 is produced.

In this case, with the minimum run length of 3T, the minimum number d=two of values “0” are included between logic values “1” and “1” in the code word C. On the other hand, with the maximum run length of 11T, the maximum number k=ten of values “0” are included between the logic values “1” and “1” in the code word C. Subsequently, the EFM signal 1 subjected to p-q modulation=8-14 modulation satisfies the run length limitation rule RLL (d, k)=RLL (2, 10) that the minimum run length is 3T and the maximum run length is 11T while direct-current components or low-frequency components of the EFM signal 1 can be reduced.

Furthermore, the EFM signal 1 including the first and second code word strings 1d, if is subjected to a non return to zero inverted (NRZI) conversion. For the NRZI conversion, as well known, the conversion is performed by inverting polarity in the bit “1” and without inverting the polarity in the bit “0”. Therefore, an NRZI-converted waveform forms a recording signal R into the glass master board. A low (L) level section in the recording signal R is made corresponding to, for example, the concave pit (or the convex land), and a high (H) level section in the recording signal R is made corresponding to, for example, the convex land (or the concave pit) to form a pit string.

Moreover, as shown in FIGS. 3A and 3B, the above-described DSV has an integral value integrated assuming “1” (positive polarity) when a waveform obtained by NRZI-converting the code word string from a start time to the present moment indicates the high (H) level and assuming “−1” (negative polarity) when the waveform indicates the low (L) level. In the NRZI conversion, the polarity is inverted at the data bit “1”. Therefore, in this case, even when two code words have the same bit pattern, the values thereof differ from each other dependent upon a waveform state subjected to the NRZI conversion immediately before connecting the code words. The DSV values have the inversion relation with each other between when the waveform state immediately before the input data word=002 is the low (L) level as shown in FIG. 3A and when the waveform state immediately before the input data word=002 is the high (H) level as shown in FIG. 3B. When the input data word=002 is connected to the input data word=253 via the connecting bit, cases shown in FIGS. 3A and 3B have the same absolute values of the DSV.

Here, while the run length limitation rule RLL(d,k)=RLL(2,10) is satisfied, any of combinations (000), (001), (010), (100) is selected and inserted as the three connecting bits 1b between the code words C and C disposed adjacent to each other so that the absolute value of the DSV substantially approaches zero. Accordingly, the direct-current components of the waveform of the recording signal R are reduced. As a result, when the waveform of the recording signal R is viewed over a long period, the high (H) level section and low (L) level section appear substantially at the same ratio. Accordingly, the DSV is controlled so that the concave pit section and convex land section appear substantially at the same ratio. It is to be noted that there are eight combinations of the three connecting bits 1b, but the combinations other than the above-described four combinations do not satisfy the run length limitation rule RLL(2,10) and are therefore deleted.

Turning back to FIG. 1, in one frame of the EFM signal 1, a synchronizing signal 1a, the connecting bits 1b, a sub-code 1c, the connecting bits 1b, the first code word string 1d, the connecting bits 1b, a C2 error correction code 1e, the connecting bits 1b, the second code word string 1f, the connecting bits 1b, a C1 error correction code 1g, and the connecting bits 1b are arranged in that order from the top of the frame, and one frame is constituted of 588 bits in total.

Here, the synchronizing signal 1a disposed in the top ranges over 24 bits, which is distinguishable from the respective signals 1b to 1g as a signal of 11T-11T in order to indicate the top of the frame.

Moreover, the sub-code 1c disposed after the synchronizing signal 1a via the three connecting bits 1b is a signal for performing reproduction control for the CD.

Furthermore, for the first code word string 1d disposed after the sub-code 1c via the three connecting bits 1b, each input data word D of p=8 bits (each music source data) is converted to each code word C of q=14 bits referring to the coding table shown in FIG. 2, and the three connecting bits 1b are inserted between the code words C and C disposed adjacent to each other. Accordingly, 12 code words C (12 symbols) and 11 connecting bits 1b constitute the first code word string 1d.

Moreover, the C2 error correction code 1e disposed after the first code word string 1d via the three connecting bits 1b performs error correction with respect to the first code word string 1d and second code word string 1f of the EFM signal 1 at a reproduction time of the CD.

Furthermore, the second code word string 1f disposed after the C2 error correction code 1e via the three connecting bits 1b is constituted of 12 code words C (12 symbols) and 11 connecting bits 1b in the same manner as the first code word string 1d.

Additionally, the C1 error correction code 1g disposed after the second code word string 1f via the three connecting bits 1b performs the error correction with respect to the first code word string 1d, second code word string 1f, and C2 error correction code 1e of the EFM signal 1 at the reproduction time of the CD.

It is to be noted that the above-described music source data may only be changed to computer source data in the description of the CD-ROM in which the computer data is recorded. Therefore, the description is omitted.

Moreover, 98 recording signals (=98 frames), each obtained by the NRZI conversion for each frame of the EFM signal 1, are continuously arranged as shown in FIG. 4 to constitute one block which is a unit of music, and this block corresponds to a period of 1/75 second.

Next, the illegal copy of the music information recorded on the CD into the CD-R will be described with reference to FIGS. 5 and 6.

FIG. 5 is a block diagram showing that the music information recorded on the CD is reproduced with a CD drive. FIG. 6 is a block diagram showing that the music information recorded on the CD is illegally copied with a CD-R drive.

As shown in FIGS. 5 and 6, it is possible for a user to play the CD on which the music information to be copied is recorded with a CD drive 20 in accordance with software for copying which is stored in a hard disk (not shown) in a personal computer (not shown) and to input the music information into a CD-R drive 40, which is outputted from the CD drive 20 and which is to be recorded in the CD-R and to illegally copy the music information to be copied as such without obtaining a copyright holder's consent.

First, as shown in FIG. 5, in the CD drive 20, a turntable 23 is solidly attached to a shaft of a spindle motor 22 which is rotated/driven at a constant linear velocity (CLV) by a spindle motor driving circuit 21. The CD is mounted on the turntable 23 so as to be rotatable integrally with the turntable 23. On a lower surface side of the CD, an optical pickup 25 connected to a laser driving circuit 24 is disposed to be movable in a diameter direction of the CD. Moreover, the laser driving circuit 24 emits a laser beam for reading from a semiconductor laser 25a in the optical pickup 25 in a rotated state of the CD. The laser beam for reading is passed through a beam splitter 25b and thereafter focused by an objective lens 25c to irradiate the signal surface of the CD with a laser beam Lp for reproduction. A return light reflected by the signal surface is detected by a four-divided-type photosensor 25d via the objective lens 25c and beam splitter 25b, and a detection signal 25e is sent to an RF signal generation circuit 26. In this case, the four-divided-type photosensor 25d is divided into four regions A to D. When a known radial push/pull method is used to add/subtract each region, a tracking error signal and focus error signal for the objective lens 25c are obtained. When the respective regions are all added, an RF signal is obtained.

The RF signal generation circuit 26 generates an RF signal 26a based on the detection signal 25e outputted from the photosensor 25d, and a binarizing circuit 27 binarizes the RF signal 26a. Accordingly, an 8-14 modulated signal 27a substantially equivalent to the recording signal R shown in FIG. 1 is obtained. Therefore, this 8-14 modulated signal 27a is sent to an 8-14 demodulation circuit 28.

The above-described 8-14 demodulation circuit 28 is schematically constituted of an NRZI inverse conversion circuit 28A, synchronizing signal detection circuit 28B, sub-code detection circuit 28C, decoding table 28D, error correction circuit 28E, and music source data demodulation circuit 28F. The 8-14 modulated signal 27a inputted into the demodulation circuit from the binarizing circuit 27 is 8-14 demodulated to reproduce the music source data AD.

Here, the NRZI inverse conversion circuit 28A returns the 8-14 modulated signal 27a inputted into the 8-14 demodulation circuit 28 from the binarizing circuit 27 back to the EFM signal 1 shown in FIG. 1 by an operation reverse to that at an NRZI conversion time. Subsequently, the synchronizing signal detection circuit 28B detects the synchronizing signal 1a from the EFM signal 1, and the sub-code detection circuit 28C detects the sub-code 1c of 14 bits from the EFM signal 1.

Moreover, each code word C of 14 bits is successively returned to each input data word D of eight bits by an operation reverse to that at a coding time with respect to the first and second code word strings 1d, 1f in the EFM signal 1 based on the decoding table 28D. Thereafter, the music source data demodulation circuit 28F combines the input data word D of the upper eight bits with the input data word D of the lower eight bits to return the data words to the music source data AD of 16 bits. This music source data AD is outputted on a CD-R drive 40 side described later from an output terminal 29. In this case, the error correction circuit 28E performs error correction with respect to the EFM signal 1 by the C2 error correction code 1e and C1 error correction code 1g in the EFM signal 1.

Therefore, the signal outputted from the output terminal 29 of the CD drive 20 is the music source data AD of 16 bits, and this data is inputted on the CD-R drive 40 side.

Next, as shown in FIG. 6, in the CD-R drive 40, a turntable 43 is solidly attached to a shaft of a spindle motor 42 which is rotated/driven at the constant linear velocity (CLV) by a spindle motor driving circuit 41. The CD-R is mounted on the turntable 43 so as to be rotatable integrally with the turntable 43. On the lower surface side of the CD-R, an optical pickup 45 connected to a laser driving circuit 44 is disposed to be movable in the diameter direction of the CD-R.

Moreover, the music source data AD of 16 bits outputted from the CD drive 20 is inputted into an 8-14 modulation circuit 47 via an input terminal 46. It is to be noted that the CD-R is beforehand formatted by a format portion (initializing portion) (not shown).

The 8-14 modulation circuit 47 is schematically constituted of a synchronizing signal addition circuit 47A, connecting bit addition circuit 47B, sub-code addition circuit 47C, coding table 47D, NRZI conversion circuit 47E, DSV control circuit 47F, error correction code addition circuit 47G, and recording signal generation circuit 47H. The music source data AD inputted into the generation circuit from the CD drive 20 is 8-14 modulated to generate the recording signal R for the CD-R.

Here, when the 8-14 modulation circuit 47 generates the EFM signal 1 shown in FIG. 1 based on the music source data AD outputted from the CD drive 20, the circuit adds the synchronizing signal 1a of 24 bits generated by the synchronizing signal addition circuit 47A to the top of the EFM signal 1 in the form of 1T-11T. Thereafter, the three connecting bits 1b generated by the connecting bit addition circuit 47B are added after the synchronizing signal 1a of 24 bits. Moreover, the sub-code addition circuit 47C adds the sub-code 1c of 14 bits after the three connecting bits 1b. Furthermore, the three connecting bits 1b are added after the sub-code 1c of 14 bits.

Moreover, the music source data AD of 16 bits inputted into the 8-14 modulation circuit 47 is divided into the input data word D of the upper eight bits and the input data word D of the lower eight bits as described above. The coding table shown in FIG. 2 is referred to with respect to these input data words D, the data words are converted to the code word C of 14 bits, and the three connecting bits 1b are inserted between the code words C and C disposed adjacent to each other to generate the first code word string 1d.

Furthermore, the error correction code addition circuit 47G adds the C2 error correction code 1e with respect to the first and second code word strings 1d, 1f after the first code word string 1d via the three connecting bits.

Additionally, the second code word string 1f is connected to the C2 error correction code 1e via the three connecting bits in the same manner as the first code word string 1d. Furthermore, the error correction code addition circuit 47G adds the C1 error correction code 1g with respect to the first and second code word strings 1d, 1f and C2 error correction code 1e after the second code word string 1f via the three connecting bits, and adds the three connecting bits after the C2 error correction code 1e to form the EFM signal 1 for the CD-R.

In this case, in the EFM signal 1, the first and second code word strings 1d, 1f are converted so as to satisfy the run length limitation rule RLL(d,k)=RLL(2,10) by the three connecting bits 1b inserted between the code words C and C disposed adjacent to each other. Moreover, the first and second code word strings 1d, 1f are subjected to the NRZI conversion by the NRZI conversion circuit 47E. Thereafter, the DSV control circuit 47F controls the DSV value by the three connecting bits 1b so that the absolute value of DSV substantially approaches zero.

Thereafter, the recording signal generation circuit 47H generates the recording signal R in the NRZI converted state of the EFM signal 1. This recording signal R is inputted into the laser driving circuit 44. When the laser driving circuit 44 supplies a laser current to a semiconductor laser 45a in the optical pickup 45 in accordance with the recording signal R, the semiconductor laser 45a emits the laser beam for recording. The laser beam for recording is passed through a beam splitter 45b and thereafter focused by an objective lens 45c to irradiate the signal surface of the CD-R with a laser beam Lr for recording, and accordingly the recording signal R (FIG. 1) by the EFM signal 1 is recorded in the signal surface.

As described above, when the music source data AD of 16 bits outputted from the CD drive 20 is coded in the CD-R drive 40, the music information recorded on the CD-R has the same EFM signal form as that of the music information recorded on the CD. Therefore, the illegally copied CD-R can further be illegally copied, and circulated in large amounts in the world.

Additionally, various methods have been studied as disks for illegal copy preventive measures in order to prevent the music information recorded on the CD or the computer data recorded on the CD-ROM as described above from being illegally copied on the CD-R or CD-RW. In Japanese Patent Application Laid-Open No. 2001-357536, optical disks such as CD-ROM and DVD-ROM, to which the illegal copy preventive measure is applied, have been disclosed.

FIG. 7 is a vertically sectional view showing the optical disk subjected to the illegal copy preventive measure as one of conventional examples. FIG. 8 is an explanatory view showing that a conventional optical disk shown in FIG. 7 is applied to the CD.

A conventional optical disk 100 shown in FIG. 7 is disclosed in the Japanese Patent Application Laid-Open No. 2001-357536. The disk will briefly be described. In the conventional optical disk 100, a concave/convex portion string which has a continuous length of 3T to 14T (T is 0.133 μm) is usually formed based on the run length limitation rule (described as a run length regulating type coding system in the publication). As characteristics of this disk, a concave or convex portion having a continuous length, which is not based on the run length limitation rule, is recorded halfway in the string.

Concretely, as shown in FIG. 7, a pit A is formed in a convex shape with a length of 1T to 2T, a pit B is formed in a concave shape with a length of 1T to 2T in a position distant from the pit A by X, and the lengths of the pits A and B indicate values which are not based on the run length limitation rule.

Moreover, a technical idea of the above-described conventional optical disk 100 is applied to the known CD on which the concave/convex portion string (pit string) having a continuous length of 3T to 11T is formed based on the run length limitation rule to modify a part of the signal form of the CD. In this case, as shown in FIG. 8, when music data is recorded between a lead-in region on an inner peripheral side of the modified CD and a lead-out region on an outer peripheral side, error correction impossible data in a shape shown in FIG. 7 may be inserted between the lead-in region and music data.

In this case, when the modified CD is played back by a commercially available optical disk drive, the error correction does not work. This is because the continuous length of 1T to 2T in the error correction impossible data is shorter than the continuous length of 3T to 11T of the usual pit string. The RF signal read using the optical pickup does not reach a sufficient bright or dark level like the RF signal obtained by reading the usual pit string. Therefore, the binarized signal obtained from the RF signal is not reproduced, and error data results. Accordingly, even when the music data recorded on the modified CD is reproduced by the commercially available optical disk drive, and a reproduction signal is inputted into the CD-R drive and copied onto the CD-R, the illegal copy is not permitted by a reproduction signal error.

However, a user who has already purchased the commercially available optical disk drive purchases the CD modified as described above. In this case, the user has to purchase a new optical disk drive which can play the modified CD, a burden on the user is enormous, and this causes a problem.

Moreover, the digital information signal recorded on the digital magnetic tape also needs to be prevented from being illegally copied.

### SUMMARY OF THE INVENTION

To solve the problem, there has been a demand for a digital information signal recording method and recording medium in which an illegal copy into a digital information signal recorded on recording mediums such as an optical disk and digital magnetic tape can beforehand be prevented while a predetermined run length limitation rule RLL(d,k) is strictly kept.

To achieve the above-described object, there is provided a digital information signal recording method comprising the steps of: converting a synchronizing signal, control signal, and input data word of p bits into a code word of q bits based on a coding table; continuously arranging, in a state of a plurality of frames, modulation signals of a unit of one frame obtained by NRZI-converting a string of code words connected to one another while strictly keeping a predetermined run length limitation rule and an error correction code to constitute data for copy prevention; and recording the data for copy prevention and a p-q modulated digital information signal on a recording medium, wherein the error correction code of the data for copy prevention is beforehand set to the same value as that of an error correction code at a copy time which is added in copying a reproduction signal of the data for copy prevention onto another recording medium, and the string of code words of the data for copy prevention is beforehand coded to be error-correctable by the error correction code beforehand set to the same value as that of the error correction code at the copy time.

In a preferred embodiment of the present invention, when the reproduction signal of the data for copy prevention obtained by correcting an error by the error correction code beforehand set to the same value as that of the error correction code at the copy time is copied on another recording medium, the string of code words of the data for copy prevention after the copy is coded so that DSV control fails at a reproduction time of the other recording medium.

In the preferred embodiment of the present invention, when the reproduction signal of the data for copy prevention obtained by correcting the error by the error correction code beforehand set to the same value as that of the error correction code at the copy time is copied on the other recording medium, the string of code words of the data for copy prevention after the copy is coded on the other recording medium so that a DSV value is largely biased toward a minus side over the plurality of frames, and thereafter the DSV value is largely biased toward a plus side over the plurality of frames, and this is alternately repeated, and the DSV control accordingly fails at the reproduction time of the other recording medium.

In the preferred embodiment of the present invention, the string of code words of the data for copy prevention is beforehand coded so that the DSV control can be performed as usual at a time when the string of code words of the data for copy prevention is error-corrected by the error correction code beforehand set to the same value as that of the error correction code at the copy time.

Moreover, to achieve the object, there is provided a recording medium on which the data for copy prevention and the p-q modulated digital information signal are recorded by the above-described digital information signal recording method.

The nature, principle and utility of the invention will become more apparent from the following detailed description when read in conjunction with the accompanying drawings.

### BRIEF DESCRIPTION OF THE DRAWINGS

In the accompanying drawings:

FIG. 1 is an explanatory view of a signal format of music information recorded on a CD;

FIG. 2 is a diagram showing a coding table at an 8-14 modulation time;

FIGS. 3A and 3B are explanatory views of a DSV control at the 8-14 modulation time;

FIG. 4 is a diagram showing that 98 EFM signals shown in FIG. 1 constitute one block;

FIG. 5 is a block diagram showing that the music information recorded on the CD is reproduced with a CD drive;

FIG. 6 is a block diagram showing that the music information recorded on the CD is illegally copied with a CD-R drive;

FIG. 7 is a vertically sectional view showing an optical disk subjected to an illegal copy preventive measure as one of conventional examples;

FIG. 8 is an explanatory view showing that a conventional optical disk shown in FIG. 7 is applied to the CD;

FIGS. 9A and 9B are explanatory views of an optical disk according to one example of a recording medium of the present invention, FIG. 9A is an appearance view, and FIG. 9B is a sectional view;

FIGS. 10A and 10B are schematic diagrams showing that data for copy prevention is inserted into a part of a recording track on the optical disk shown in FIGS. 9A and 9B, FIG. 10A shows the CD on which music data is recorded, and FIG. 10B shows a CD-R on which computer data is recorded;

FIGS. 11A to 11D are explanatory views schematically showing data for copy prevention which is a major part of the present invention, FIG. 11A shows a recording state onto the optical disk which is one example of the recording medium according to the present invention, FIG. 11B shows, a reproduction state of the optical disk which is one example of the recording medium according to the present invention, FIG. 11C shows a copy recording state onto a CD-R, and FIG. 11D shows a copy reproduction state of the CD-R;

FIG. 12 is a diagram showing a DSV value of each frame of the data for copy prevention at a time when the data for copy prevention as the major part of the present invention is illegally copied on the CD-R;

FIGS. 13A and 13B are diagrams showing a first signal form of a code word string of the data for copy prevention illegally copied on the CD-R, and a tendency of a DSV value, respectively;

FIGS. 14A and 14B are diagrams showing a second signal form of the code word string of the data for copy prevention illegally copied on the CD-R, and the tendency of the DSV value, respectively;

FIGS. 15A and 15B are diagrams showing a third signal form of the code word string of the data for copy prevention illegally copied on the CD-R, and the tendency of the DSV value, respectively;

FIGS. 16A and 16B are diagrams showing a fourth signal form of the code word string of the data for copy prevention illegally copied on the CD-R, and the tendency of the DSV value, respectively;

FIG. 17 is an enlarged view of a binarizing circuit in the CD drive; and

FIGS. 18A to 18C are explanatory views of a binarizing process at a DSV control time in playing the optical disk as one example of the recording medium according to the present invention or the illegally copied CD-R in the CD drive, FIG. 18A shows that the DSV value of the code word string of the data for copy prevention subjected to error correction normally varies at a time when the optical disk of the present invention is played back, FIG. 18B shows that the DSV value is largely biased toward a minus side by the data for copy prevention when the illegally copied CD-R is played back, and FIG. 18C shows that the DSV value is largely biased toward a plus side by the data for copy prevention when the illegally copied CD-R is played back.

### DESCRIPTION OF THE PREFERRED EMBODIMENTS

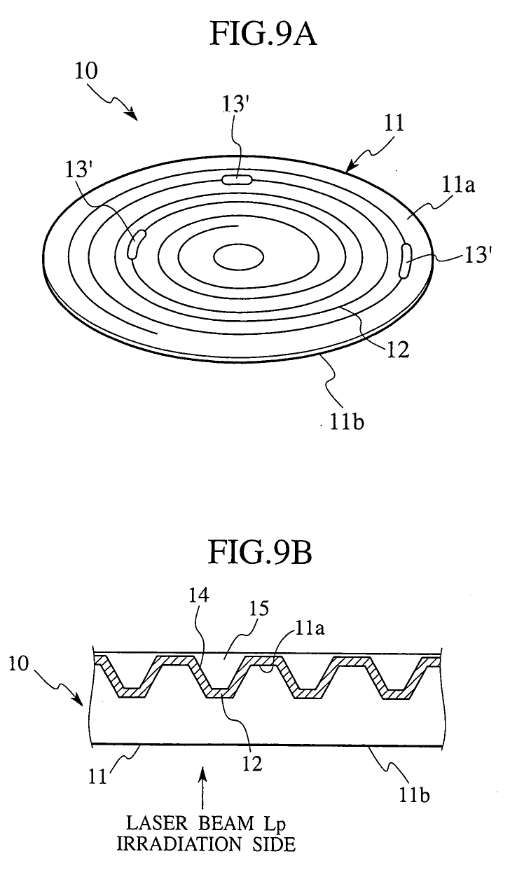

One embodiment of a digital information signal recording method and recording medium according to the present invention will be described hereinafter in detail with reference to FIGS. 9A to 18C.

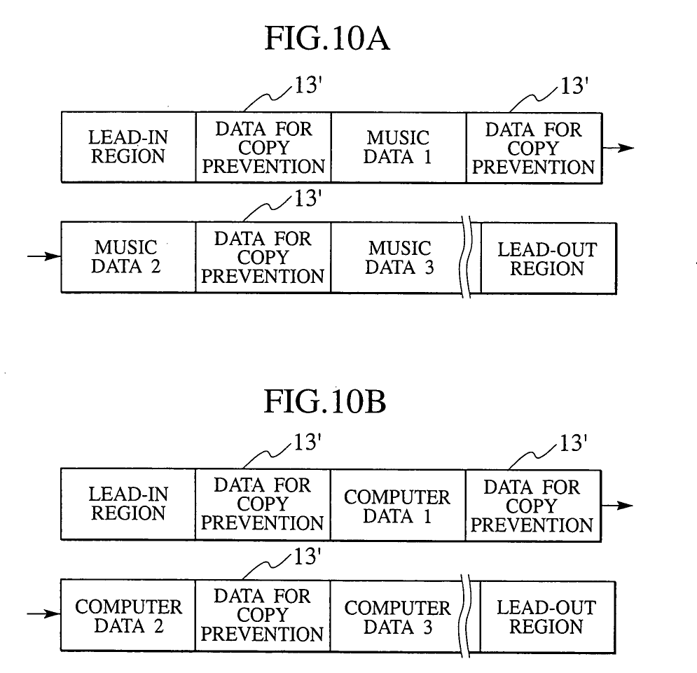

FIGS. 9A and 9B are explanatory views of an optical disk which is one example of the recording medium according to the present invention, FIG. 9A is an appearance view, and FIG. 9B is a sectional view. FIGS. 10A and 10B are schematic diagrams showing that data for copy prevention is inserted into a part of a recording track on the optical disk shown in FIGS. 9A and 9B, FIG. 10A shows a CD on which music data is recorded, and FIG. 10B shows a CD-R on which computer data is recorded.

It is to be noted that for the sake of convenience of description, the same constituting members as those described above in the related art are denoted with the same reference numerals and appropriately described. Additionally, constituting members different from those of the related art are denoted with new reference numerals, and respects different from those of the related art will mainly be described in this embodiment.

In the digital information signal recording method according to the present invention, a synchronizing signal, control signal, and input data word of p bits are converted into a code word of q bits based on a coding table. Modulation signals of a one frame unit obtained by NRZI-converting a code word string of the code words connected to one another while strictly keeping a predetermined run length limitation rule RLL(d,k), and an error correction code are arranged for a plurality of frames to constitute the data for copy prevention. The data for copy prevention and a p-q modulated digital information signal are recorded on recording mediums such as the optical disk and a digital magnetic tape. In this case, especially the error correction code of the data for copy prevention is beforehand set to the same value as that of an error correction code at a copy time, which is added in copying a reproduction signal of the data for copy prevention onto another recording medium. Moreover, the code word string of the data for copy prevention is beforehand coded to be error-correctable by the error correction code beforehand set to the same value as that of the error correction code at the copy time.

Accordingly, even when a conventional reproduction apparatus is used as such, the digital information signal can be reproduced without any trouble from a recording medium with the data for copy prevention and p-q modulated digital information signal recorded therein. On the other hand, the reproduction signal of the data for copy prevention at a reproduction time of the recording medium is copied on another recording medium. When the other recording medium is played back, the DSV control of the code word string of the data for copy prevention fails and the reproduction becomes impossible. Therefore, illegal copy of the digital information signal can be prevented in advance.

It is to be noted that in the embodiment described hereinafter, the optical disks such as CD and CD-R will be described as one example of the recording medium on which the digital information signal is recorded. As described above, the technical idea of the present invention can also be applied to the digital magnetic tape on which the digital information signal is recorded as described above.

As shown in FIGS. 9A and 9B, a recording medium 10 on which data for copy prevention 13′ is recorded together with the digital information signal by the digital information signal recording method is applied to the optical disks for the exclusive use in reproduction such as a compact disc (CD) on which music information is recorded and a CD-read only memory (CD-ROM) on which computer data is recorded. Various types of digital information signals recorded on this recording medium (hereinafter referred to as the optical disk) 10 are coded so as to satisfy a run length limitation rule RLL(d,k)=RLL(2,10) that a minimum run length is 3T and maximum run length is 11T as a top priority by an eight to fourteen modulation (EFM: 8-14 modulation) system for use in the CD.

For the optical disk 10, on one surface 11a of a disc-shaped transparent disk substrate 11 which has an outer diameter of 120 mm or 80 mm, a hole diameter of 15 mm of a center hole, and a substrate thickness of 1.2 mm, the digital information signal is converted to a digital string of pits by concave pits and convex lands, and this pit string is carved as a spiral or concentric recording track 12 to be recorded as a signal surface.

Here, the embodiment of the present invention is different from the related art in that the data for copy prevention 13′ is coded and recorded in the form of an EFM signal in an error-correctable state while strictly keeping the run length limitation rule RLL(2,10) on a part of the recording track 12. Furthermore, a metal reflective film 14 and protective film 15 are formed in that order on the signal surface of the optical disk 10, and the optical disk 10 is formed for the exclusive use in reproduction. Moreover, a surface 11b disposed opposite to one surface 11a of the transparent disk substrate 11 is on a side irradiated with a laser beam Lp for reproduction.

In this case, the data for copy prevention 13′ is recorded on a part of the recording track 12 as shown in FIGS. 10A and 10B.

That is, for the CD on which the music information is recorded, as shown in FIG. 10A, for example, when a plurality of music data 1, 2, 3 . . . are recorded between a lead-in region on an inner peripheral side and a lead-out region on an outer peripheral side, the data for copy prevention 13′ may be inserted in soundless regions between the music data not to influence the respective music data 1, 2, 3 . . . In this case, each music data is recorded in the form of the EFM signal, and 98 frames of EFM signals correspond to 1/75 second, as described above. Therefore, when a recording period of the data for copy prevention 13′ is set over an extremely short time of about 1/(75×(10 to 15)) seconds, it is possible to reproduce the data for copy prevention 13′ without being heard by a user.

Moreover, for the CD-R on which the computer data is recorded, as shown in FIG. 10B, for example, when a plurality of computer data 1, 2, 3 . . . are recorded between the lead-in region on the inner peripheral side and the lead-out region on the outer peripheral side, the data for copy prevention 13′ may be inserted in unrecorded regions between the computer data not to influence the respective computer data 1, 2, 3 . . .

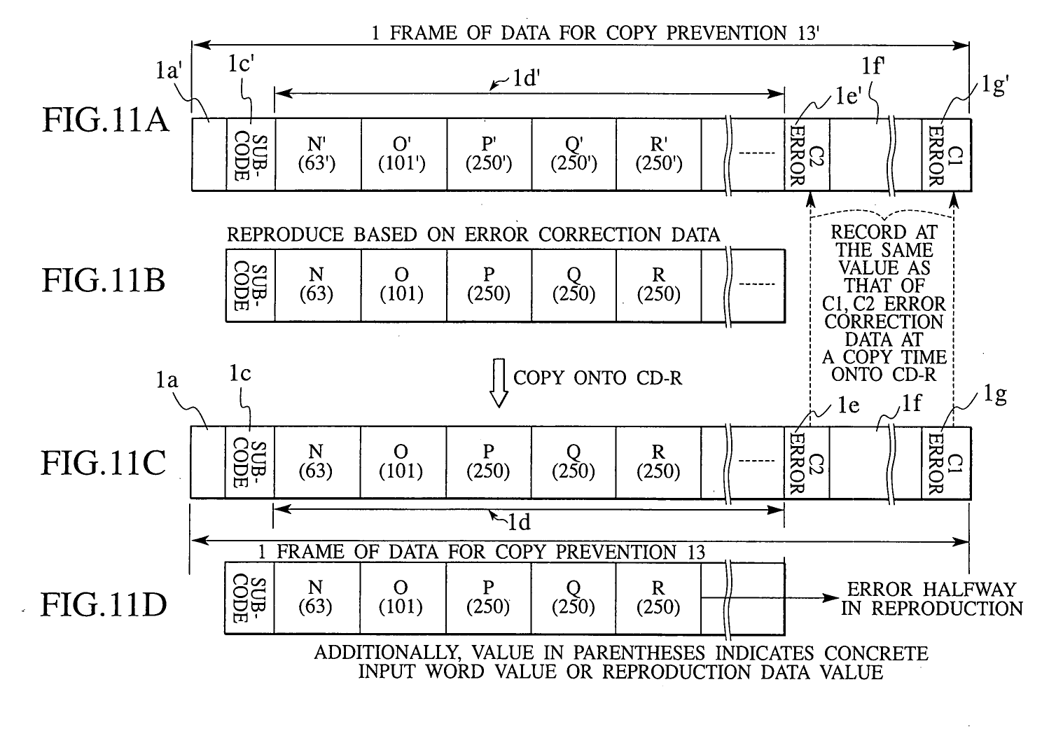

Next, the data for copy prevention which is a major part of the present invention will be described with reference to FIGS. 11 to 16.

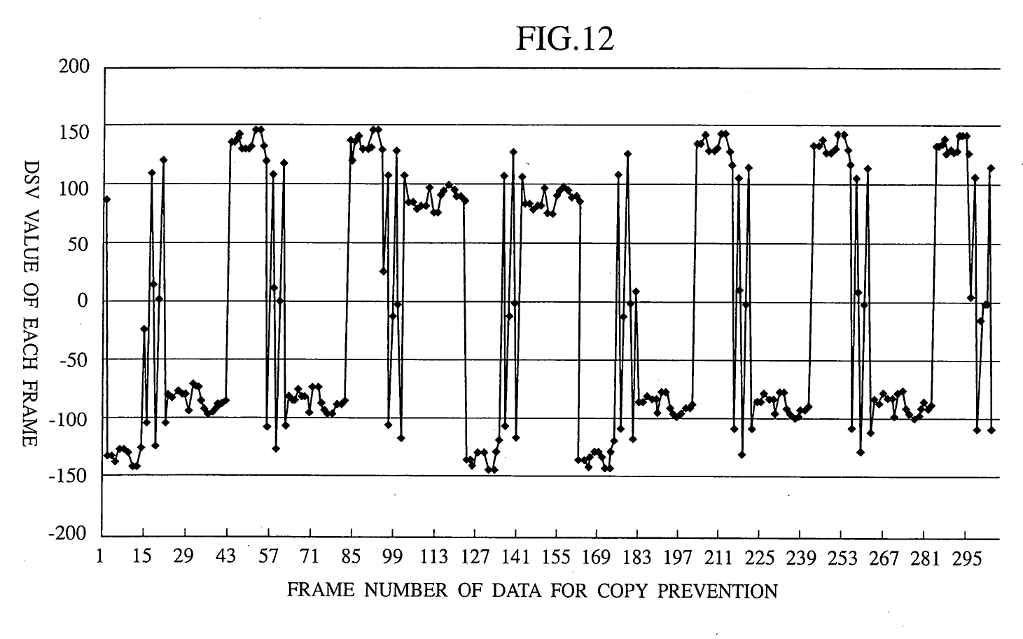

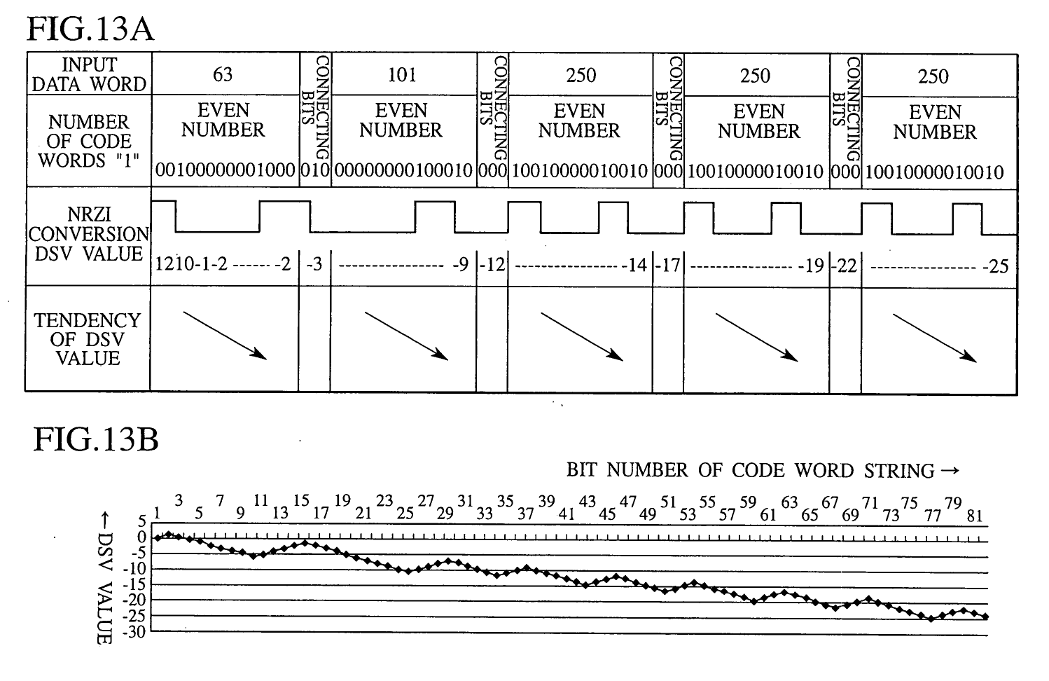

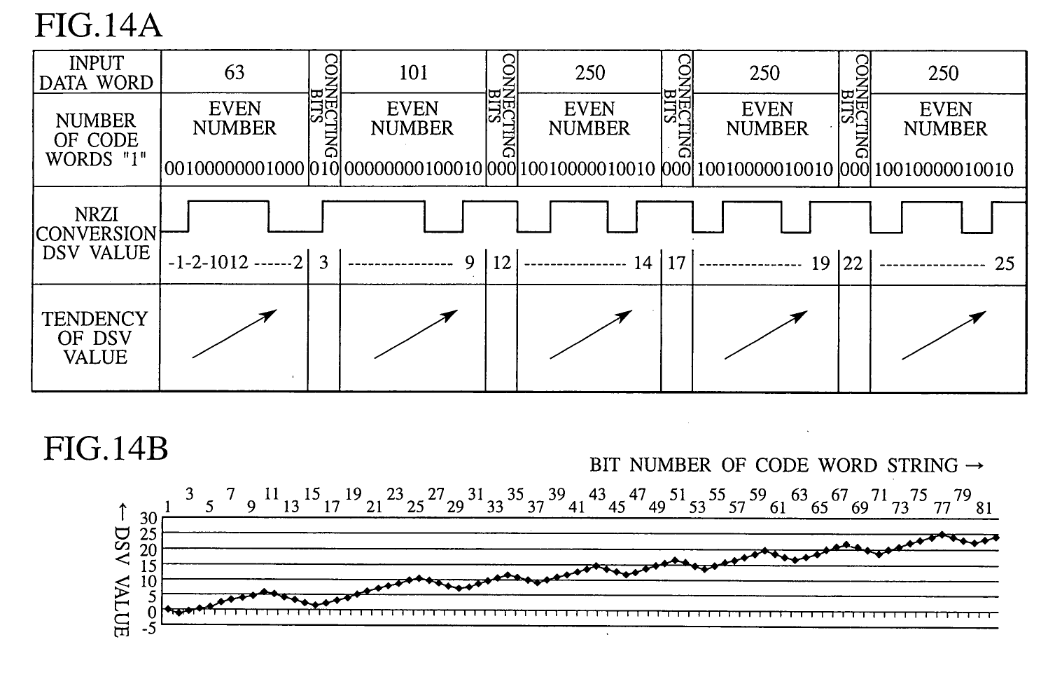

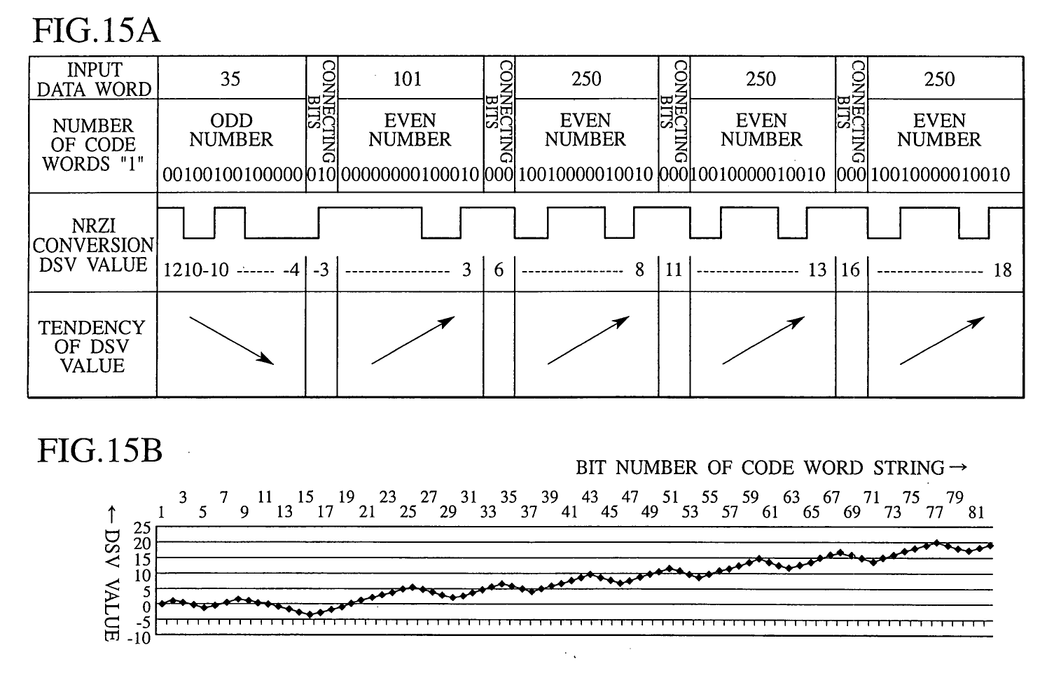

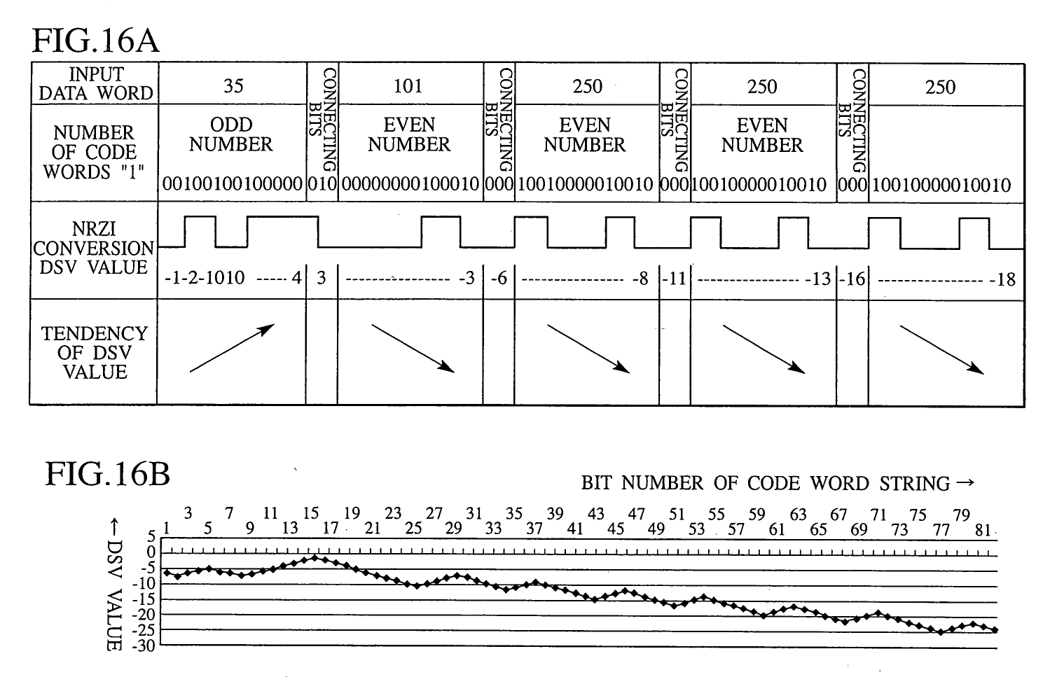

FIGS. 11A to 11D are explanatory views schematically showing the data for copy prevention which is the major part of the present invention, FIG. 11A shows a recording state onto the optical disk which is one example of the recording medium according to the present invention, FIG. 11B shows a reproduction state of the optical disk which is one example of the recording medium according to the present invention, FIG. 11C shows a copy recording state onto a CD-R, and FIG. 11D shows a copy reproduction state of the CD-R. FIG. 12 is a diagram showing a DSV value of each frame of the data for copy prevention at a time when the data for copy prevention as the major part of the present invention is illegally copied on the CD-R. FIGS. 13A and 13B are diagrams showing a first signal form of the code word string of the data for copy prevention illegally copied on the CD-R, and a tendency of the DSV value, respectively. FIGS. 14A and 14B are diagrams showing a second signal form of the code word string of the data for copy prevention illegally copied on the CD-R, and the tendency of the DSV value, respectively. FIGS. 15A and 15B are diagrams showing a third signal form of the code word string of the data for copy prevention illegally copied on the CD-R, and the tendency of the DSV value, respectively. FIGS. 16A and 16B are diagrams showing a fourth signal form of the code word string of the data for copy prevention illegally copied on the CD-R, and the tendency of the DSV value, respectively.

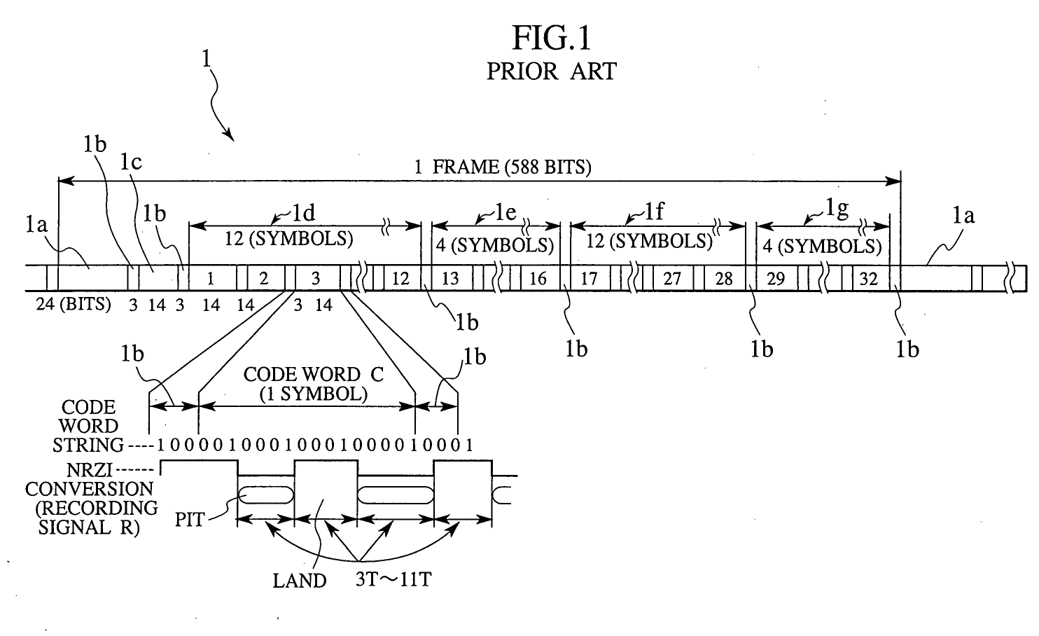

A plurality of frames of the data for copy prevention 13′ which is the major part of the present invention are continuously recorded for a short time in the EFM signal form described above with reference to FIG. 1 on the optical disk 10 (FIG. 9A) which is one example of the recording medium according to the present invention. The short-time recording of the plurality of frames of the data for copy prevention 13′ is regarded as one set, and a plurality of sets are appropriately scattered and recorded on the optical disk 10 (FIG. 9A) as shown in FIGS. 10A and 10B.

That is, as shown in FIG. 11A, one frame of the data for copy prevention 13′ recorded on the recording medium 10 (FIG. 9A) is constituted of a synchronizing signal 1a′, sub-code 1c′, first code word string 1d′, C2 error correction code 1e′, second code word string 1f′, and C1 error correction code 1g′ in that order in the same manner as in the related art. Needless to say, one frame of the data for copy prevention 13′ is coded so as to satisfy the run length limitation rule RLL(2,10) as the top priority. Although not shown herein, the three connecting bits 1b (FIG. 1) are added in the same manner as in the related art. Moreover, the data for copy prevention 13′ is constituted of a plurality of continuous modulation signals arranged by one frame unit of the data for copy prevention 13′.

In this case, it is assumed that the music data or computer data recorded together with the data for copy prevention 13′ on the recording medium 10 (FIG. 9A) constituting one example of the recording medium according to the present invention is recorded as the EFM signal 1 (FIG. 1) by the 8-14 modulation in the same manner as in the related art.

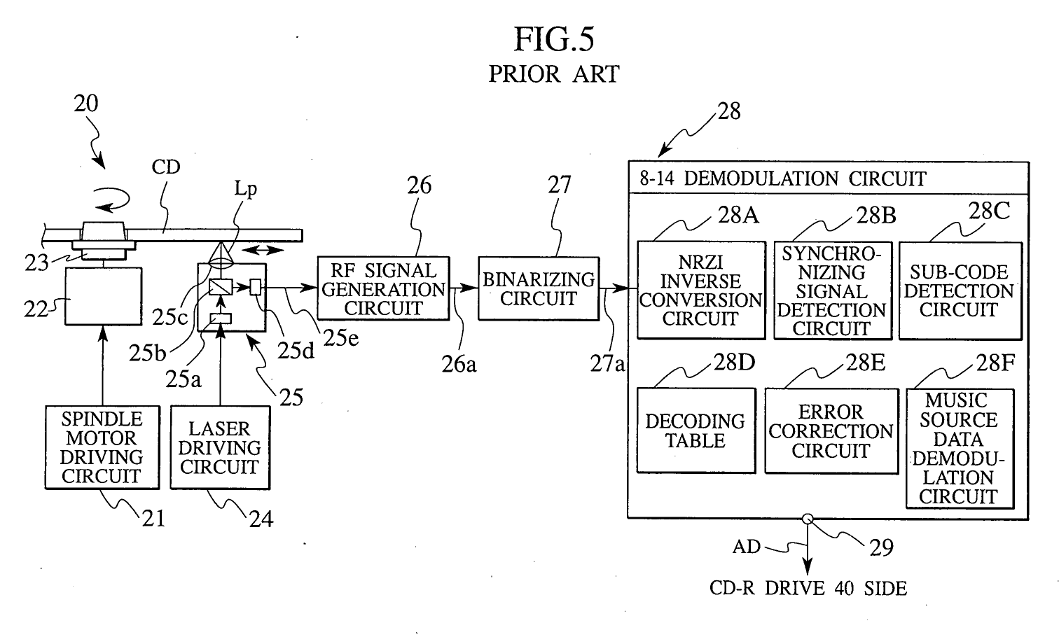

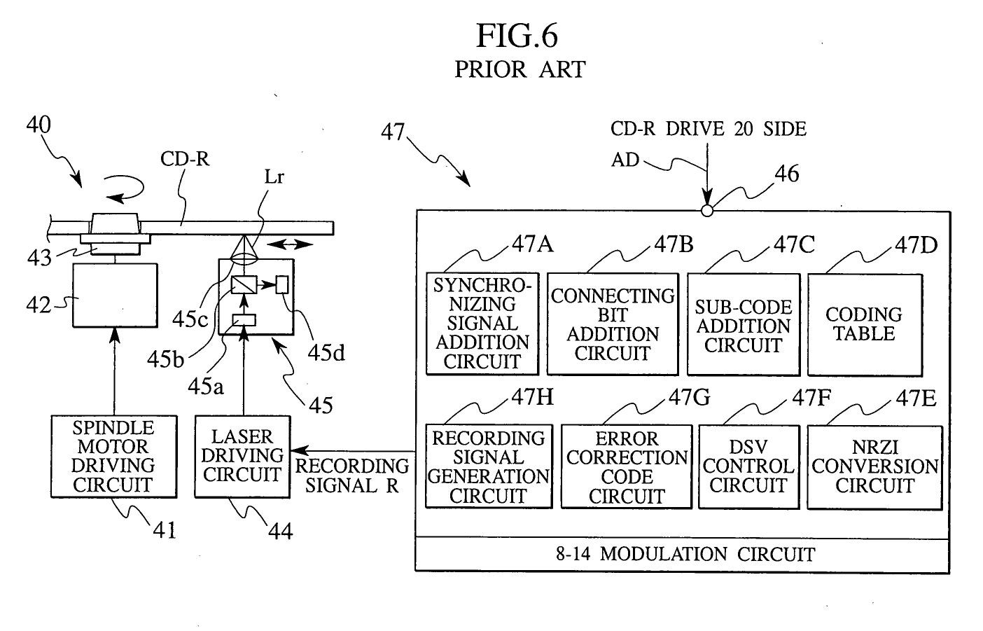

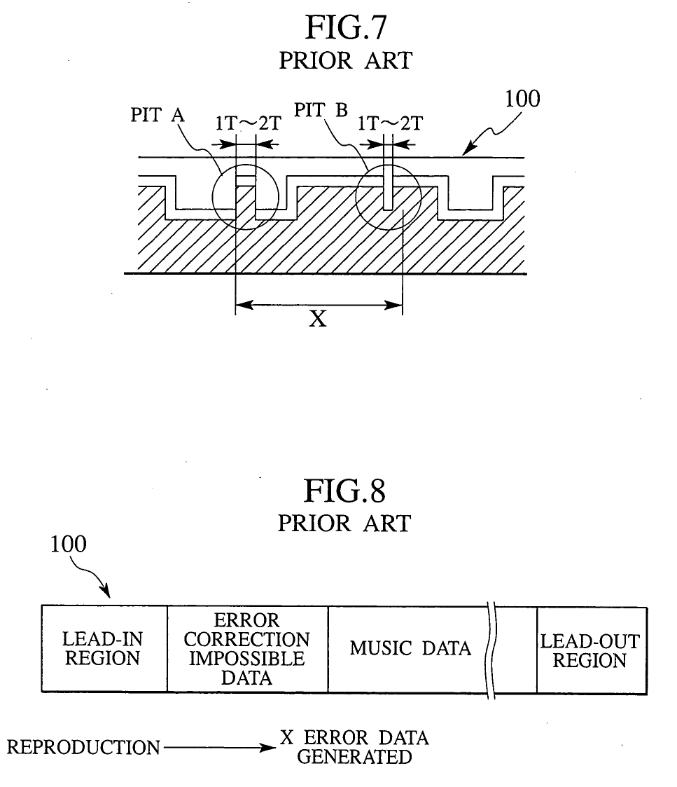

Here, respects of one frame of the data for copy prevention 13′ different from that of the conventional EFM signal 1 (FIG. 1) will be described. When one frame of the data for copy prevention 13′ is copied as data for copy prevention 13 on the CD-R as shown in FIG. 11C, the C2 error correction code 1e′ and C1 error correction code 1g′ are beforehand set to the same values as those of the C2 error correction code 1e and C1 error correction code 1g given in the CD-R drive 40 (FIG. 6). Further, the respective code words of the first code word string 1d′ and second code word string 1f′ are coded to be error-correctable by the C2 error correction code 1e′ and C1 error correction code 1g′.

Furthermore, the data for copy prevention 13′ is coded so that the first code word string 1d′ and second code word string 1f′ coded to be error-correctable can satisfactorily be reproduced in a DSV control range without any trouble in the conventional CD drive 20 (FIG. 5). However, the data for copy prevention 13′ is beforehand coded so that the first code word string 1d and second code word string 1f of the data for copy prevention 13 on the CD-R exceed a control range of DSV and reveal flaws and thus the reproduction is impossible when the data for copy prevention 13′ is illegally copied on the CD-R with the error correction by the C2 error correction code 1e′ and C1 error correction code 1g′.

Additionally, each code word of the first code word string 1d′ in one frame of the data for copy prevention 13′ recorded on the optical disk 10 constituting one example of the recording medium according to the present invention is recorded in a state before the error correction as shown in FIG. 11A. For example, N′, O′, P′, Q′, R′, . . . are coded to be error-correctable and to be in a DSV controllable range and arranged from the top of the first code word string 1d′. More concretely, for example, N′, O′, P′, Q′, R′, . . . are recorded in that order from the top of the first code word string 1d′ in accordance with each input data word of the code word string shown in FIGS. 13 and 14 described later. More concretely, (63′), (101′), (250′), (250′), (250′), . . . are recorded. Needless to say, the second code word string 1f′ in one frame of the data for copy prevention 13′ recorded on the optical disk 10 is beforehand coded to be error-correctable and to be in the DSV controllable range substantially in the same manner as the first code word string 1d′.

Moreover, the optical disk 10 on which the data for copy prevention 13′ is recorded is played back using the conventional CD drive 20 (FIG. 5). Then, the disk can be played back without any trouble, because the plurality of frames of the data for copy prevention 13′ are coded to be error-correctable and to be in the DSV controllable range as described above. For example, when one frame of the data for copy prevention 13′ is reproduced, the first code word string 1d′ is reproduced after the sub-code 1c′ is reproduced. In this case, for each code word of the first code word string 1d′, any error is corrected by the C2 error correction code 1e′ and C1 error correction code 1g′ indicating the same values as those at the copy time. Therefore, as shown in FIG. 11B, different from the record time, N, O, P, Q, R, . . . are reproduced in that order from the top of the first code word string. More concretely, corresponding to the recording time, (63), (101), (250), (250), (250), . . . are reproduced, and the reproduced data is inputted as such into the CD-R drive 40 (FIG. 6). Needless to say, the second code word string 1f′ in one frame of the data for copy prevention 13′ is also reproduced in the state in which any error has been corrected by the C2 error correction code 1e′ and C1 error correction code 1g′ having the same values as those at the copy time substantially in the same manner as in the first code word string 1d′, and inputted into the CD-R drive 40.

Next, reproduction data obtained by playing the optical disk 10 on which the data for copy prevention 13′ is recorded is inputted into the CD-R drive 40 (FIG. 6). Then, as shown in FIG. 11C, the synchronizing signal 1a is added in the CD-R drive 40 and recorded into the top of one frame of the data for copy prevention 13 on the CD-R. The subsequently generated sub-code 1c and first code word string 1d are copied/recorded like N(63), O(101), P(250), Q(250), R(250), . . . in that order from the top in the same state as that of the reproduction data. Moreover, the second code word string 1f is copied/recorded in the same manner as the first code word string 1d. Furthermore, the C2 error correction code 1e and C1 error correction code 1g for the first and second code word strings 1d, if are given in the CD-R drive 40 and recorded. In this case, the data for copy prevention 13 recorded on the CD-R is coded so as to satisfy the run length limitation rule RLL(2,10) as the top priority. Moreover, the data for copy prevention 13 recorded on the CD-R is beforehand set so as to depart from the control range of the DSV as described later.

It is to be noted that the music data or computer data recorded on the optical disk 10 constituting one example of the recording medium according to the present invention is illegally copied as such on the CD-R in the same manner as in the related art.

Here, each code word of the first code word string 1d′ in one frame of the data for copy prevention 13′ is recorded on the optical disk 10 (FIG. 9A) like N′(63′), O′(101′), P′(250′), Q′(250′), R′(250′), . . . When the code words are illegally copied on the CD-R, the respective code words of the first code word string 1d in one frame of the illegally copied data for copy prevention 13 are coded and recorded like N(63), O(101), P(250), Q(250), R(250), . . . However, as described later, the first code word string 1d of the data for copy prevention 13 illegally copied is coded so that the DSV value exceeds the control range and is largely biased toward the minus or plus side by the arrangement of the above-described respective code words. Needless to say, the illegally copied second code word string 1f of the data for copy prevention 13 is coded so that the DSV value is largely biased toward the minus or plus side in the same tendency as that of the illegally copied first code word string 1d.

Moreover, when the data for copy prevention 13 is illegally copied continuously in the plurality of frames on the CD-R, and when the illegally copied CD-R is played back as shown in FIG. 11D, the DSV value largely lowers on the minus side or largely rises on the plus side by the plurality of frames of data for copy prevention 13. Therefore, the illegally copied CD-R cannot be played back, the error is generated, and the reproduction is stopped. This will be described later.

The plurality of continuous frames of the data for copy prevention 13′ are illegally copied onto the CD-R from the optical disk 10 (FIG. 9A) constituting one example of the recording medium according to the present invention. In this case, as shown in FIG. 12, the plurality of continuous frames of the data for copy prevention 13′ are beforehand set on the side of the optical disk 10 (FIG. 9A) so that the DSV values of about 10 to 20 frames of the data for copy prevention 13 on the CD-R will be continuously biased toward the minus side largely, and thereafter the DSV values of about 10 to 20 frames of the data for copy prevention 13 will be continuously biased toward the plus side largely, and this is repeated a plurality of times so that the DSV values are alternately inverted toward the minus or plus side for each predetermined number of frames.

This will more concretely be described. The code word string of the data for copy prevention 13 on the illegally copied CD-R is roughly classified into: first and second signal forms in which the DSV value over all the code words of the code word string continuously shifts in one direction (on the minus or plus side) as shown in FIGS. 13A, 13B, 14A, 14B; and third and fourth signal forms in which the DSV value changes direction to the plus side from the minus side or to the minus side from the plus side over the code word string as shown in FIGS. 15A, 15B, 16A, 16B.

First, in the first and second signal forms shown in FIGS. 13A and 13B and FIGS. 14A and 14B, the input data words each having eight bits, such as 63, 101, 250, 250, 250, . . . are arranged from the top of the code word string of the data for copy prevention 13 on the CD-R. Each input data word of eight bits is 8-14 modulated into each code word of 14 bits. Moreover, while the run length limitation rule RLL(2,10) is strictly kept as the top priority, the three connecting bits are inserted between the code words to form the code word string. Thereafter, at an NRZI conversion time, the code word string shown in FIGS. 13A and 13B is the same as that shown in FIGS. 14A and 14B. However, the DSV values become different from each other dependent upon a waveform state subjected to the NRZI conversion immediately before connecting the top code word as described above, but the absolute values of the DSV values become equal to each other. Also in this case, a combination which strictly keeps the run length limitation rule RLL(2,10) as the top priority is selected from the combinations of the three connecting bits (000), (001), (010), (100) for between the code words, and thus the code words are connected to each other via the connecting bits.

Therefore, in the first signal form by the code word string of the data for copy prevention 13 on the CD-R shown in FIGS. 13A and 13B, the NRZI-converted waveform state immediately before the top code word is connected is a high (H) level. Therefore, the DSV value over all the code words in the code word string gradually shifts toward the minus side.

On the other hand, in the second signal form shown in FIGS. 14A and 14B, the NRZI-converted waveform state immediately before the top code word is connected is a low (L) level. Therefore, the DSV value over all the code words in the code word string gradually shifts toward the plus side.

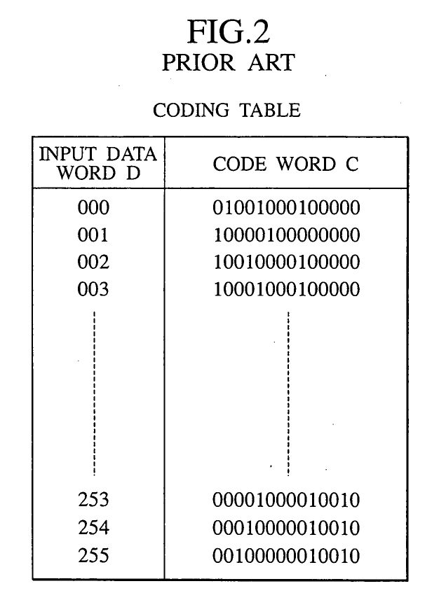

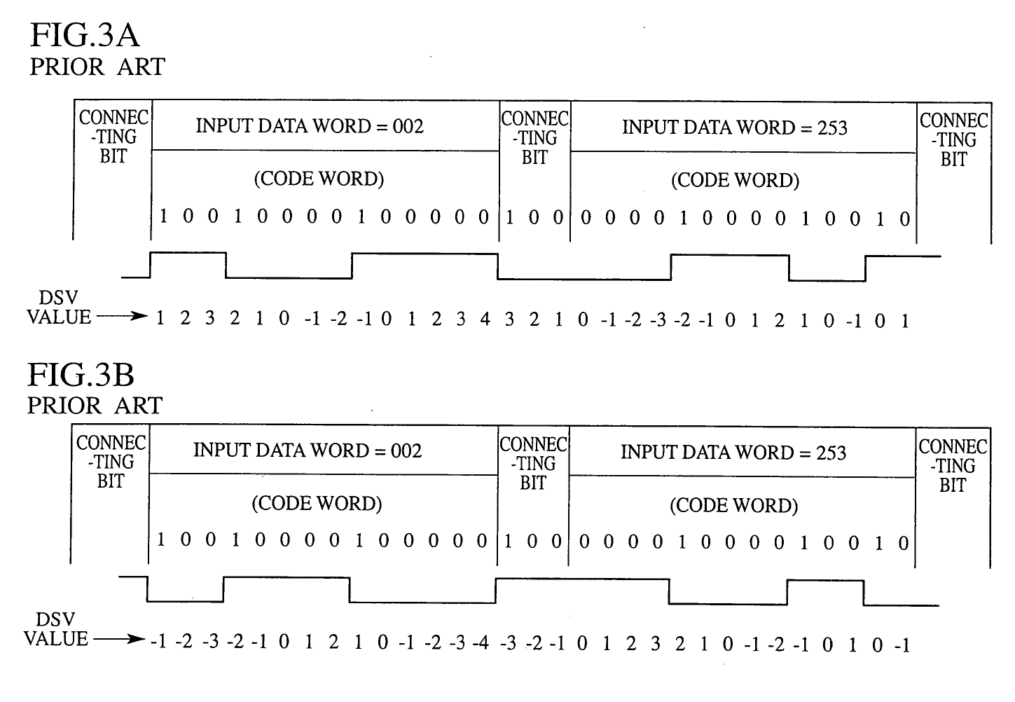

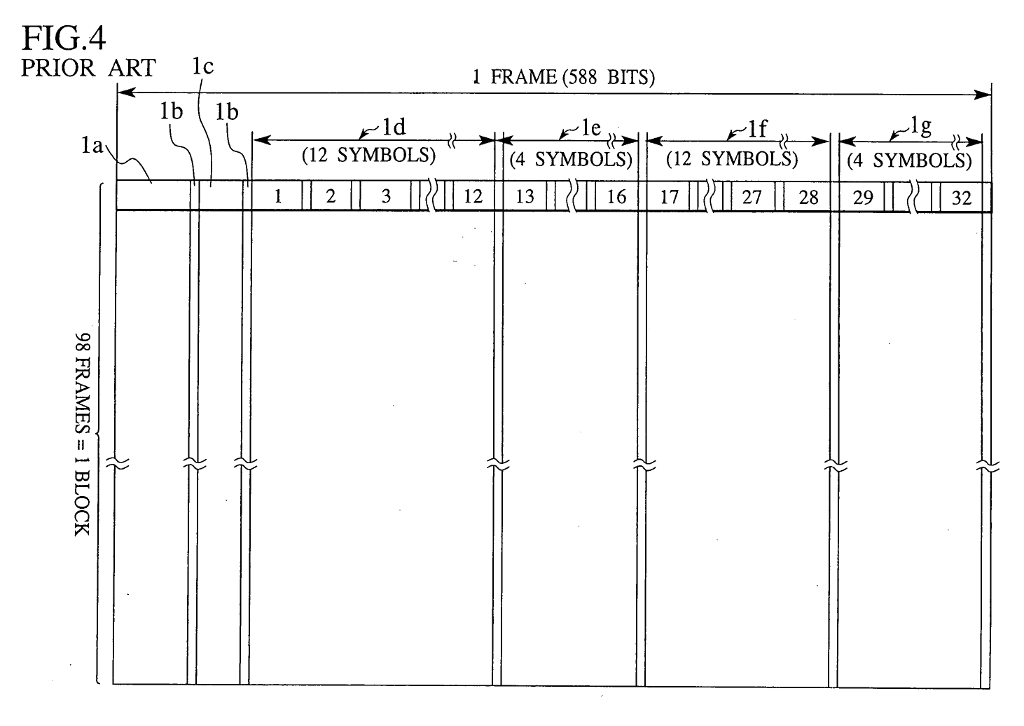

In this case, each of the values 63, 101, 250, 250, 250, . . . described as the input data word is merely one example. Therefore, other code words whose DSV values shift in one direction (on the minus or plus side) may be selected as the codeword string from the coding table shown in FIG. 2.

Moreover, for the code word string of the data for copy prevention 13 on the CD-R shown in FIGS. 13A, 13B, 14A, 14B, the code words are beforehand selected so that each of the DSV values of the top, second, and third code words shifts in one direction (minus or plus side). Then, when the same code words as the third code word are arranged as fourth and subsequent code words, the DSV value over the whole code word string shifts in one direction (minus or plus side). Furthermore, when all the DSV values of the code words of the code word string shift in one direction (minus or plus side), the number of “1” in each code word is an even number.

Next, in the third and fourth signal forms shown in FIGS. 15A and 15B and FIGS. 16A and 16B, the input data words each having eight bits, such as 35, 101, 250, 250, 250, . . . are arranged from the top of the code word string of the data for copy prevention 13 on the CD-R. Each input data word of eight bits is 8-14 modulated into each code word of 14 bits. Moreover, while the run length limitation rule RLL(2,10) is strictly kept as the top priority, the three connecting bits are inserted between the code words to form the code word string. Thereafter, at the NRZI conversion time, the code word string shown in FIGS. 15A and 15B is the same as that shown in FIGS. 16A and 16B. However, the DSV values become different from each other dependent upon a waveform state subjected to the NRZI conversion immediately before connecting the top code word as described above, but the absolute values of the DSV values become equal to each other. Also in this case, a combination which strictly keeps the run length limitation rule RLL(2,10) as the top priority is selected from the combinations of the three connecting bits (000), (001), (010), (100) for between the code words, and thus the code words are connected to each other via the connecting bits.

Therefore, in the third signal form by the code word string of the data for copy prevention 13 on the CD-R shown in FIGS. 15A and 15B, the NRZI-converted waveform state immediately before the top code word is connected is a high (H) level. Therefore, the code words are arranged so that the DSV value of the top code word shifts toward the minus side, subsequently the DSV value of the second code word changes the direction on the plus side, and all the DSV values of the third and subsequent code words gradually shifts towards the plus side.

On the other hand, in the fourth signal form shown in FIGS. 16A and 16B, the NRZI-converted waveform state immediately before the top code word is connected is a low (L) level. Therefore, the code words are arranged so that the DSV value of the top code word shifts toward the plus side, subsequently the DSV value of the second code word changes the direction on the minus side, and all the DSV values of the third and subsequent code words gradually shifts toward the minus side.

In this case, each of the values 35, 101, 250, 250, 250, . . . described as the input data word is merely one example. Therefore, other code words whose DSV values change the direction to the plus side from the minus side or to the minus side from the plus side may be selected as the code word string from the coding table shown in FIG. 2.

Moreover, for the code word string of the data for copy prevention 13 on the CD-R shown in FIGS. 15A, 15B, 16A, 16B, the top code word is beforehand selected for the direction change with respect to the second code word. Then, the second and subsequent code words can be set to the same values as those of FIGS. 13A, 13B, 14A, 14B. In this case, for the top code word selected for the direction change, the number of “1” in the code word is an odd number. The number of “1” in the second and subsequent code words is an even number in the same manner as described above.

Furthermore, the first to fourth signal forms shown in FIGS. 13A to 16B are used to record the data so that the DSV value of the data for copy prevention 13 is largely biased alternately on the minus and plus sides over the plurality of frames on the illegally copied CD-R as shown in FIG. 12. In this case, to continuously largely shift the DSV value toward the minus or plus side substantially over 10 to 20 frames, the first and second signal forms which have one directionality as shown in FIGS. 13A, 13B, 14A, 14B may continuously be used. On the other hand, to change the direction of the DSV value to the plus side from the minus side or to the plus side from the minus side, the third and fourth signal forms which have direction change properties as shown in FIGS. 15A, 15B, 16A, 16B may be used.

Accordingly, the data for copy prevention 13′ on the optical disk 10 (FIG. 9A) constituting one example of the recording medium according to the present invention may beforehand be coded so that the data for copy prevention 13 coded using the first to fourth signal forms shown in FIGS. 13A to 16B is obtained by the error correction on the CD-R.

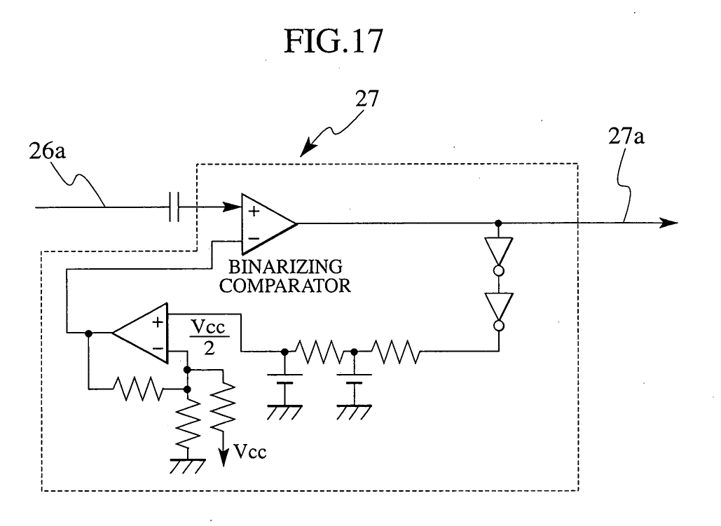

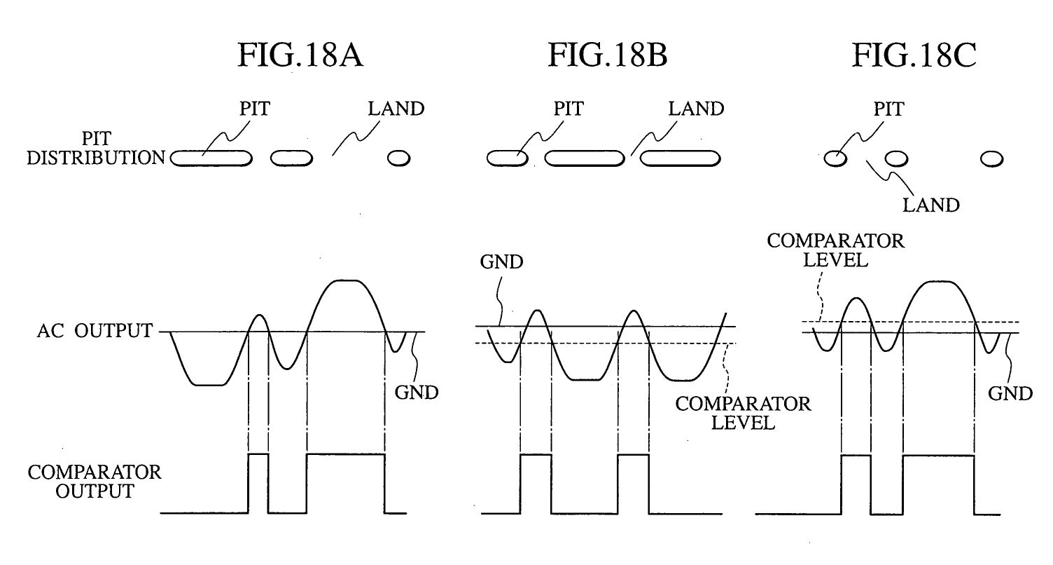

Next, the data for copy prevention 13 on the optical disk 10 (FIG. 9A) constituting one example of the recording medium according to the present invention or the illegally copied CD-R is played back with the conventional CD drive 20 (FIG. 5). This case will be described with reference to FIGS. 17, 18A to 18C.

FIG. 17 is an enlarged view of a binarizing circuit in the CD drive. FIGS. 18A to 18C are explanatory views of a binarizing process at a DSV control time in playing back the optical disk as one example of the recording medium according to the present invention or the illegally copied CD-R in the CD drive. FIG. 18A shows that the DSV value of the code word string of the data for copy prevention subjected to the error correction normally varies at a time when the optical disk of the present invention is played back. FIG. 18B shows that the DSV value is largely biased toward the minus side by the data for copy prevention when the illegally copied CD-R is played back. FIG. 18C shows that the DSV value is largely biased toward the plus side by the data for copy prevention when the illegally copied CD-R is played back.

The data for copy prevention 13 on the optical disk 10 (FIG. 9A) constituting one example of the recording medium according to the present invention or the illegally copied CD-R is played back with the conventional CD drive 20 (FIG. 5). In this case, as described above with reference to FIG. 5, the RF signal 26a from the RF signal generation circuit 26 is supplied to the binarizing circuit 27.

As enlarged and shown in FIG. 17, the binarizing circuit 27 is constituted using electronic components such as a binarizing comparator, resistance, and capacitor. The RF signal 26a from the RF signal generation circuit 26 is binarized to obtain the 8-14 modulated signal 27a.

Here, as shown in FIG. 18A, when the optical disk 10 (FIG. 9A) constituting one example of the recording medium according to the present invention is played back, the error of the data for copy prevention 13′ is corrected. The DSV control is performed in such a manner that the absolute value of DSV of the code word string of the error-corrected data for copy prevention 13′ substantially approaches zero. Therefore, a ratio of a section of a pit to that of a land substantially becomes equal in a period when the DSV values are integrated. Accordingly, the section of the low (L) level of the binarizing signal is substantially equal to that of the high (H) level in the period when the DSV values are integrated. By such a feedback that an average value of slice levels is substantially Vcc/2 in the binarizing circuit 27, the 8-14 modulated signal 27a binarized without any trouble can be obtained. Thereafter, the binarized 8-14 modulated signal 27a is supplied to a PLL circuit (not shown). This PLL circuit can generate a clock to control the spindle motor 22 (FIG. 5) at the constant linear velocity (CLV). Therefore, a reproduction operation is normally performed.

Next, as shown in FIG. 18B, when the data for copy prevention 13 on the illegally copied CD-R is played back, and when the DSV value of the code word string of the data for copy prevention 13 is largely biased toward the minus side, the section of the pit largely increases in the period when the DSV values are integrated. On the other hand, the section of the land largely decreases. Accordingly, the section of the low (L) level of the binarizing signal largely lengthens in the period when the DSV values are integrated. On the other hand, the section of the high (H) level largely shortens. Even by the feedback is performed so that the average value of slice levels is substantially Vcc/2 in the binarizing circuit 27, the slice level largely lowers, and therefore the normal binarizing process cannot be performed. Therefore, even when an abnormal 8-14 modulated signal 27a obtained in the binarizing circuit 27 is supplied to the PLL circuit (not shown), the PLL circuit does not generate any clock, and the spindle motor 22 (FIG. 5) cannot normally be CLV-controlled. As a result, the illegally copied music data (or computer data) cannot be reproduced.

Next, as shown in FIG. 18C, when the data for copy prevention 13 on the illegally copied CD-R is played back, and when the DSV value of the code word string of the data for copy prevention 13 is largely biased toward the plus side, the section of the pit largely decreases in the period when the DSV values are integrated. On the other hand, the section of the land largely increases. Accordingly, the section of the low (L) level of the binarizing signal largely shortens in the period when the DSV values are integrated. On the other hand, the section of the high (H) level largely lengthens. Even by the feedback is performed so that the average value of slice levels is substantially Vcc/2 in the binarizing circuit 27, the slice level largely rises, and therefore the normal binarizing process cannot be performed. Therefore, as described above, even when the abnormal 8-14 modulated signal 27a obtained in the binarizing circuit 27 is supplied to the PLL circuit (not shown), the PLL circuit does not generate any clock, and the spindle motor 22 (FIG. 5) cannot normally be CLV-controlled. As a result, the illegally copied music data (or computer data) cannot be reproduced.

Moreover, in the state of FIGS. 18B and 18C, as described above with reference to FIG. 12, the data for copy prevention 13 on the CD-R corresponds to the state in which the DSV values of about 10 to 20 frames thereof are continuously largely biased toward the minus side, thereafter the DSV values of about 10 to 20 frames thereof are continuously largely biased toward the plus side, and this is repeated a plurality of times. Therefore, when the data for copy prevention 13 is reproduced, the reproduction operation is stopped. Therefore, it is possible to prevent, in advance, copyright infringement onto the digital information signal on the CD-R illegally copied using the optical disk 10 (FIG. 9A) constituting one example of the recording medium according to the present invention.

It is to be noted that in the digital information signal recording method and recording medium according to the present invention described above in detail, the EFM modulation (8-14 modulation) system for use in the CD has been described. However, the present invention is not limited to this. A technical idea that the data for copy prevention is beforehand recorded on the optical disk can be applied even to 8-16 modulation, such as an EFM+′ system for use in a known digital versatile disc (DVD) for higher densification of information as compared with CD. In the modulation, each inputted data word of p bits=eight bits is converted to each code word of q bits=16 bits. Additionally, while strictly keeping the predetermined run length limitation rule, the code word of q bits=16 bits is directly connected to another code word without using the connecting bits.

Furthermore, to further achieve the information densification higher than that of DVD, a new signal format has been studied for a next-generation optical disk. Even in this case, the technical idea that the data for copy prevention is beforehand recorded on the optical disk can be applied even to p-q modulation. In the modulation, each input data word of p bits is converted to each code word of q bits. Additionally, while strictly keeping the predetermined run length limitation rule, the code word of q bits is directly connected to the other code word without using the connecting bits. Even in either case, the error correction code which has the same value as that of the error correction code in the code word string of the data for copy prevention on the illegally copied optical disk is beforehand set in the code word string of the data for copy prevention on a real optical disk. Additionally, the code word string of the data for copy prevention on the real optical disk is beforehand coded to be error-correctable so that the DSV value of the code word string of the data for copy prevention on the illegally copied optical disk reveals flaws. Needless to say, in each above-described case, for the data for copy prevention on the optical disk, the signal format of the DVD or the next-generation optical disk may be applied.

As described above in detail, in the digital information signal recording method according to the present invention, the synchronizing signal, control signal, and input data word of p bits are converted into the code word of q bits based on the coding table. The modulation signals of the unit of one frame obtained by NRZI-converting the string of code words connected to one another while strictly keeping the predetermined run length limitation rule, and the error correction code are arranged f or the plurality of frames to constitute the data for copy prevention. The data for copy prevention and p-q modulated digital information signal are recorded on the recording mediums such as the optical disk and digital magnetic tape. In this case, especially the error correction code of the data for copy prevention is beforehand set to the same value as that of the error correction code at the copy time, which is added in copying the reproduction signal of the data for copy prevention into another recording medium. Moreover, the string of code words of the data for copy prevention is beforehand coded to be error-correctable by the error correction code beforehand set to the same value as that of the error correction code at the copy time. Therefore, when the reproduction signal of the data for copy prevention is copied onto the other recording medium, the DSV control at the reproduction time of the other recording medium fails and the reproduction becomes impossible. Therefore, the illegal copy of the digital information signal can beforehand be prevented.

Moreover, for the recording medium according to the present invention, even when the conventional reproduction apparatus is used as such, the digital information signal can be reproduced without any trouble. Moreover, the illegal copy of the digital information signal can be prevented in advance by the data for copy prevention.

It should be understood that many modifications and adaptations of the invention will become apparent to those skilled in the art and it is intended to encompass such obvious modifications and changes in the scope of the claims appended hereto.

What is claimed is:

1. A digital information signal recording method comprising the steps of:
converting a synchronizing signal, control signal, and input data word of p bits into a code word of q bits based on a coding table;
continuously arranging, in a state of a plurality of frames, modulation signals of a unit of one frame obtained by NRZI-converting a string of code words connected to one another while strictly keeping a predetermined run length limitation rule and an error correction code to constitute data for copy prevention; and
recording the data for copy prevention and a p-q modulated digital information signal on a recording medium,
wherein the error correction code of the data for copy prevention is beforehand set to the same value as that of an error correction code at a copy time, which is added in copying a reproduction signal of the data for copy prevention onto another recording medium, and the string of code words of the data for copy prevention is beforehand coded to be error-correctable by the error correction code beforehand set to the same value as that of the error correction code at the copy time.

2. The digital information signal recording method according to claim 1, wherein the string of code words of the data for copy prevention after the copy is coded so that DSV control fails at a reproduction time of the other recording medium, when the reproduction signal of the data for copy prevention obtained by correcting an error by the error correction code beforehand set to the same value as that of the error correction code at the copy time is copied on the other recording medium.

3. The digital information signal recording method according to claim 1, wherein the string of code words of the data for copy prevention after the copy is coded on the other recording medium so that a DSV value is largely biased toward a minus side over the plurality of frames, and thereafter the DSV value is largely biased toward a plus side over the plurality of frames, and this is alternately repeated, and the DSV control accordingly fails at the reproduction time of the other recording medium, when the reproduction signal of the data for copy prevention obtained by correcting an error by the error correction code beforehand set to the same value as that of the error correction code at the copy time is copied on the other recording medium.

4. The digital information signal recording method according to claim 1, wherein the string of code words of the data for copy prevention is beforehand coded so that the DSV control can be performed as usual at a time when the string of code words of the data for copy prevention is error-corrected by the error correction code beforehand set to the same value as that of the error correction code at the copy time.

5. A recording medium on which the data for copy prevention and p-q modulated digital information signal are recorded by the digital information signal recording method according to claim 1.
